(19) United States
(12) Patent Application Publication
(10) Pub. No.: US 2022/0068653 A1
(43) Pub. Date: Mar. 3, 2022

(54) METHOD FOR ETCHING A III-N MATERIAL LAYER

(71) Applicant: COMMISSARIAT A L'ENERGIE ATOMIQUE ET AUX ENERGIES ALTERNATIVES, Paris (FR)

(72) Inventors: Nicolas POSSEME, Grenoble Cedex 09 (FR); Simon RUEL, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 17/446,723

(22) Filed: Sep. 2, 2021

(30) Foreign Application Priority Data
Sep. 3, 2020 (FR) 20 08958

(51) Int. Cl. H01L 21/3065; H01L 29/205; H01J 37/32

(52) U.S. Cl. CPC H01L 21/3065; H01L 29/66462; H01J 37/321; H01L 29/205

(57) ABSTRACT

A method for etching at least one portion of a III-N material layer, including the implementation of the following steps of:
a) first etching of a first part of the thickness of the portion of the III-N material layer, implemented by using a first plasma including chlorine;
b) exposing at least one part of a remaining thickness of the portion of the III-N material layer to a second plasma including helium or hydrogen;
c) chlorinating the part of the remaining thickness of the portion of the III-N material layer, transforming the part of the remaining thickness of the portion of the III-N material layer into a chlorinated material layer;
d) second etching of the chlorinated material layer, implemented by using a third plasma including argon.

### TECHNICAL FIELD

The invention relates to a method for etching a III-N material layer. The invention also relates to a method for making one or more power electronic components during which this etching method is implemented.

### PRIOR ART

By virtue of their better electrical properties than those of silicon or SiC-based structures, AlGaN/GaN heterostructures, which allow the formation of a two-dimensional electron gas, are a judicious choice for making power electronic components such as HEMTs (High-Electron-Mobility Transistor) or diodes. Advantages provided by this type of heterostructure are especially the small size of the components that can be made, good voltage withstand, high carrier mobility and low series resistance.

This heterostructure, when used to make a transistor or diode, is etched to form the locations for the gate and electrical contacts of the transistor, or to form the locations for the electrical contacts of the diode. For this, plasma etching is implemented in an ICP (Inductive Coupled Plasma) type equipment by using a chlorinated plasma, for example SiCl₄ or BCl₃. The rate of such etching is high by virtue of the desorption of the GaCl₃ and AlCl₃ species which are volatile. However, it induces defects in the etched heterostructure, as for example: creation of structural defects, modification of stoichiometry or implantation of elements and generation of charges in the etched materials. These defects modify electrical properties of the etched materials and degrade those of the device made from the etched heterostructure, as for example the transistor channel when this etching is implemented to make the transistor gate. Furthermore, such plasma etching does not allow good control of the depth of etched material due to the absence of an etch stop layer in the etched structure, as this depth is determined by the period of time during which etching is implemented.

Documents “Reactive ion etching of gallium nitride using hydrogen bromide plasmas” by A. T. Ping et al. Electron. Lett, vol. 30, no. 22, pp. 1895-1897, 1994, and “Reactive ion etching of GaN using CHF₃/Ar and C₂ClF₅/Ar plasmas” by H. Lee et al, Appl. Phys. Lett, vol. 67, p. 1754, 1995, describe the possibility of etching GaN by using bromine- or fluorine-based plasmas. However, the etching rates obtained are much lower than those obtained by using chlorine-based plasmas due to the species formed being more difficult to desorb than those formed by chlorine-based plasmas. An increase in the ionic energy of the plasma used increases the etching rate, but results in defects in the etched material.

To overcome these problems, document “Atomic layer etching of GaN and AlGaN using directional plasma-enhanced approach,” by T. Ohba et al, Jpn. J. Appl. Phys. vol. 56, no. 6, 2017 suggests to implement conventional chlorine plasma etching followed by ALE (“Atomic Layer Etching”) type over-etching to etch a GaN layer. This over-etching is achieved by cyclically repeating the following two steps of:
chlorinating by Cl₂/BCl₃ plasma the GaN surface to be etched, modifying the GaN to a small thickness and forming a thin Cl₂-based layer;
etching the Cl₂-based layer selectively with respect to the GaN underneath the Cl₂-based layer that has not been modified by the previous chlorination step, implemented by an Ar-based plasma with a low bias.

Between each of the two steps of each over-etching cycle, it is necessary to perform a purge and stabilisation of the gases for about 10 seconds. During this phase, the plasma is switched off to avoid interactions and mixing of gases. Given the numerous over-etching cycles required to etch the desired thickness (as the thickness of material etched in each cycle is in the order of 0.5 nm), the time required to implement this method represents a major drawback. In addition, the range of ion energy values with which the etching of the Cl₂-based layers has to be implemented to completely etch the Cl2-based layer without damaging the underlying GaN is very restricted.

### DISCLOSURE OF THE INVENTION

Thus there is a need to provide a method for etching at least one portion of a III-N material layer that is faster than etching implemented with a bromine- or fluorine-based plasma or that implements an ALE type over-etching, and that achieves better accuracy of the etched material thickness than chlorine-based plasma etching.

For this, a method for etching at least one portion of a III-N material layer is provided, including implementing the following steps of:

a) first etching of a first part of the thickness of the portion of the III-N material layer, implemented by using a first plasma including chlorine;

b) exposing at least one part of a remaining thickness of the portion of the III-N material layer to a second plasma including helium or hydrogen;

c) chlorinating the part of the remaining thickness of the portion of the III-N material layer, transforming the part of the remaining thickness of the portion of the III-N material layer into a chlorinated material layer;

d) second etching of the chlorinated material layer, implemented by using a third plasma including argon.

This method implements a first etching of the portion of the III-N material layer by using a first plasma including chlorine to rapidly etch a first part of the thickness of the portion of the III-N material layer to be etched. In the step a), the first plasma including chlorine etches, or remove, the material of the first part of the thickness of the portion of the III-N material. Steps b), c) and d) which are then implemented one or more times complete etching of the portion of the III-N material layer.

In comparison with etching using only chlorine plasma, damage to the etched material caused by the method here described is no greater, or even less, and this etching method allows better control of the depth of etched material because this depth is defined by the thickness of material exposed in step b).

In comparison with etching using bromine or fluorine-based plasmas, the etching rate achieved with the method here described is higher, and this without having to increase the ionic energy of the plasmas used, which could cause many defects in the etched material.

Finally, in comparison with the ALE method using Cl₂— and Ar-based plasmas, the method provided here allows for a higher etching rate due to the thickness of material which can be etched during the implementation of steps b), c) and d) being much higher than that which can be etched during an ALE over-etching cycle.

Steps b), c) and d) may be repeated one or more times until a desired etch depth is achieved.

Step b) and/or step d) may be implemented by subjecting the second plasma and/or the third plasma to a bias voltage of between 20V and 100V. Such bias voltages allow defects created in the material to be limited.

The part of the remaining thickness of the III-N material layer portion may have a thickness of between 5 nm and 10 nm.

Step c) may be implemented by using a chlorine solution or a fourth plasma including Cl₂ and/or BCl₃.

Steps b), c) and d), and optionally step a), may be implemented in a single ICP-RIE (“Inductive Coupled Plasma—Reactive Ion Etching”) type etching equipment.

Step b) and/or step d) may be implemented with a pulsed plasma. The use of a pulsed plasma reduces the damage to the etched layer for a given self-bias voltage, and reduces damage in comparison with a continuous plasma.

Step b) and/or step d) may be implemented:
by using a power source of between 100 W and 1000 W, and/or
in an etching chamber in which the pressure is between 0.67 Pa and 6.67 Pa, and/or
with a plasma flow of between 10 sccm and 500 sccm, and/or
for a period of time of between 5 s and 20 s, and/or wherein step c) may be implemented:
by using a power source of between 100 W and 1000 W, and/or
in an etching chamber in which the pressure is between 1.33 Pa and 13.33 Pa, and/or
with a flow of between 10 sccm and 500 sccm, and/or
for a period of time of between 5 s and 30 s.

The method is advantageously implemented to etch a III-N material layer including GaN and/or AlGaN and/or AlN.

Further, the III-N material layer may be part of an AlGaN/GaN heterostructure.

It is also described a method for making at least one power electronic component, including the implementation of the following steps of:
making an AlGaN/GaN heterostructure;
making locations for the electrical contacts of the power electronic component in the AlGaN/GaN heterostructure, including implementing an etching method as described above.

### BRIEF DESCRIPTION OF THE DRAWINGS

The present invention will be better understood upon reading the description of exemplary embodiments given by way of illustrating and in no way limiting purposes with reference to the appended drawings in which:

FIG. 1 schematically shows the steps of a method for etching at least one portion of a III-N material layer according to a particular embodiment;

FIGS. 2 to 7 schematically show the steps of a part of a method for making a power electronic component according to a particular embodiment.

Identical, similar or equivalent parts of the different figures described hereinafter bear the same numerical references so as to facilitate switching from one figure to another.

The different parts shown in the figures are not necessarily shown to a uniform scale, in order to make the figures more legible.

The various possibilities (alternatives and embodiments) should be understood as not being exclusive of each other and can be combined with each other.

### DETAILED DISCLOSURE OF PARTICULAR EMBODIMENTS

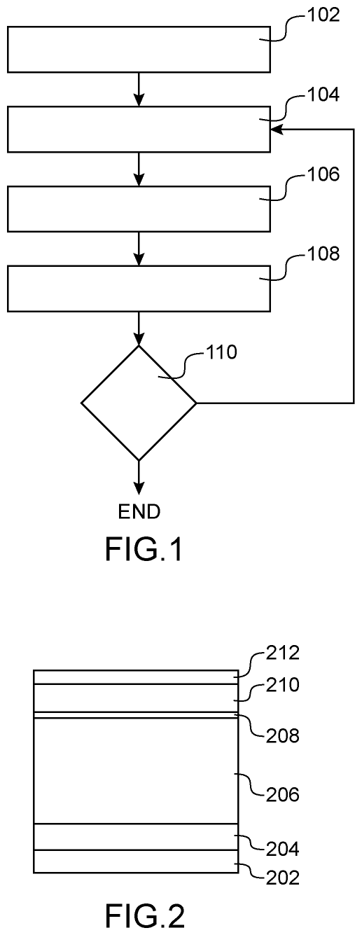

FIG. 1, described below, schematically shows the steps of a method for etching at least one portion of at least one III-N material layer according to a particular embodiment.

The III-N material layer here corresponds to a GaN and/or AlGaN and/or AlN layer. However, other III-N materials may be etched with the method described below.

The thickness of the portion of the III-N material layer to be etched is for example between 20 nm and 400 nm.

This etching method is implemented here in a single RIE type etching equipment, and advantageously ICP-RIE type.

A first part of the thickness of the portion of the III-N material layer is first etched during a first etching 102. This first etching 102 is implemented by using a first plasma including chlorine, with the addition of for example BCl₃ or SiCl₄.

This first etching 102 is implemented for a period of time sufficient to etch a large part of the thickness of the portion of the III-N material layer to be etched, for example between about 80% and 90% of that thickness. The value of the remaining thickness to be etched (after the first etching) of the portion of the III-N material layer may be between about 5 nm and 50 nm.

After implementing this first etching 102, exposing 104 at least one part of the remaining thickness of the portion of the III-N material layer to a second plasma including helium or hydrogen is implemented. By exposing the III-N material to helium or hydrogen in this way, the III-N material undergoes amorphisation and is damaged by the helium or hydrogen used, creating defects in the III-N material that form broken and/or pendant atomic bonds. This modification of the III-N material is carried out to a thickness of, for example, between 5 nm and 10 nm.

During this step 104 exposing the III-N material to the second plasma including helium or hydrogen, the second plasma may be subjected to a bias voltage of between 20V and 100V, and advantageously equal to 50V.

This step 104 is for example implemented:
by using a power source of between 100 W and 1000 W, and advantageously equal to 100 W, and/or
in an etching chamber in which the pressure is between 0.67 Pa and 6.67 Pa, and advantageously equal to 1.33 Pa, and/or
with a plasma flow of between 10 sccm and 500 sccm, and advantageously equal to 200 sccm, and/or
for a period of between 5 s and 20 s, and advantageously equal to 5 s.

A step 106 of chlorinating the part of the remaining thickness of the portion of the III-N material layer modified by the previous step 104 is then implemented, transforming this part of the remaining thickness of the portion of the III-N material layer into a chlorinated material layer. Chlorine to which the damaged III-N material is exposed is adsorbed by virtue of the broken and/or pendant atomic bonds previously formed by the implementation of step 104.

The thickness of the obtained chlorinated material layer is substantially equal to that of the previously damaged III-N material, that is of between 5 nm and 10 nm.

The chlorination step 106 may be implemented by using a chlorine solution or a fourth plasma including Cl₂ and/or BCl₃.

This chlorination step 106 is for example implemented:
by using a power source of between 100 W and 1000 W, and advantageously equal to 100 W, and/or
in an etching chamber in which the pressure is between 1.33 Pa and 13.33 Pa, and advantageously equal to 8 Pa, and/or
with a flow of between 10 sccm and 500 sccm, and advantageously equal to 200 sccm, and/or
for a period of time of between 5 s and 30 s, that is the time required to adsorb chlorine over the entire zone of III-N material previously damaged.

A second etching 108 of the chlorinated material layer obtained at the end of the previous chlorination step 106 is then implemented by using a third plasma including argon. This second etching 108 enables the entire thickness of the chlorinated material layer to be etched.

During this second etching 108, the third plasma including argon may be subjected to a bias voltage of between 20V and 100V, and advantageously equal to 50V.

This second etching 108 is for example implemented:
by using a power source of between 100 W and 1000 W, and advantageously equal to 100 W, and/or
in an etching chamber in which the pressure is between 0.67 Pa and 6.67 Pa, and advantageously equal to 1.33 Pa, and/or
with a plasma flow of between 10 sccm and 500 sccm, and advantageously equal to 200 sccm, and/or
for a period of time of between 5 s and 20 s.

Optionally, between steps 104 and 106 and/or between steps 106 and 108, a stabilisation step may be implemented in order to stabilise the gases, pressure and temperature before implementing the next step. This stabilisation step may be implemented for a period of time of a few seconds.

In step 110, the user decides whether the desired etch depth has been achieved. If yes, the etching method is completed. If not, steps 104, 106 and 108 are repeated one or more times until the desired etch depth is achieved in the portion of the III-N material layer.

All of the steps of the method described above may be implemented at the same temperature below 100° C., and advantageously between 40° C. and 60° C. to have a better material modification efficiency.

When the steps of the method are implemented at a temperature of 40° C., each cycle of implementation of steps 104-110 may etch a material thickness of about 1.4 nm.

As an alternative to the method described above, the exposure 104 of the III-N material to the second plasma including helium or hydrogen and/or the second etching 108 using the third plasma including argon may be implemented with a pulsed plasma. Such a pulsed plasma may be achieved by intermittently, that is periodically, operating the source and/or the bias. The properties of this pulsed plasma may be adjusted by modifying the duty cycle (ratio of on-time to off-time) and/or the frequency of the signal controlling the power of the source, and/or by modifying the duty cycle and/or the frequency of the bias signal.

The etching method described above is advantageously implemented in making power electronic components. FIGS. 2 to 7 described below illustrate steps implemented when making a power electronic component 200 for etching a given thickness of an AlGaN/GaN heterostructure. The steps described in connection with FIGS. 2 to 7 correspond to the steps implemented to make the gate of a HEMT transistor.

The HEMT transistor is made from a stack of layers including a substrate 202, one or more buffer layers 204 arranged on the substrate 202, and an AlGaN/GaN heterostructure formed here by a GaN layer 206 arranged on the buffer layer(s) 204, an AlN layer 208 arranged on the GaN layer 206 and an AlGaN layer 210 arranged on the AlN layer 208. The layers 204, 206, 208 and 210 are made, for example, by epitaxy. The substrate 202 corresponds to a semiconductor substrate, for example silicon. The buffer layer(s) 204, which reduce the problems of lattice mismatch and thermal expansion coefficients between the substrate 202 and the AlGaN/GaN heterostructure, include, for example, AlN and/or AlGaN in different concentrations to create a gradient of Al and/or Ga, allowing the AlGaN/GaN heterostructure to be epitaxially grown under proper conditions.

The thickness of the AlGaN/GaN heterostructure (layers 206, 208, 210) is for example of between 300 nm and 1 μm.

In the example described here, the AlGaN layer 210 is covered by a thin passivation layer 212 of SiN, with a thickness of, for example, 10 nm, deposited in-situ in the epitaxy frame used to make the layers 204, 206, 208 and 210, making it possible to protect the upper surface of the AlGaN layer 210, and to avoid relaxations as well as opening of dislocations on the surface of the AlGaN layer 210. The structure obtained at this stage of the method corresponds to the structure visible in FIG. 2.

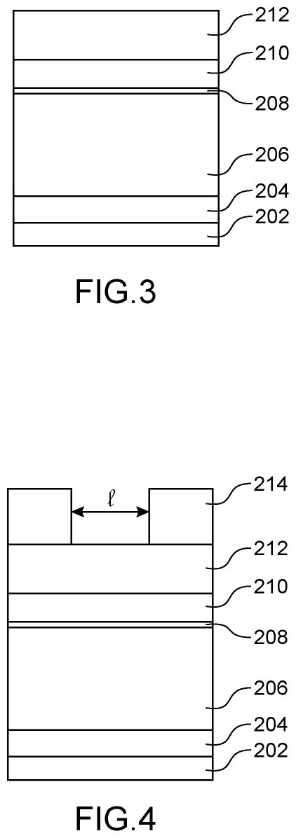

The passivation layer 212 may then be completed by depositing, for example by LPCVD (Low-Pressure Chemical Vapor Deposition), a greater thickness of passivation material, here silicon nitride (Si₃N₄). The final thickness of the passivation layer is for example of between 10 nm and 100 nm. The structure obtained at this stage of the method corresponds to the structure visible in FIG. 3.

An etch mask 214 is then made on the passivation layer 212. The pattern of this etch mask 214 is used to define the shape and location of the gate of the transistor made. This pattern corresponds, for example, to that of a trench whose width “I” is, for example, of between 250 nm and 50 μm. This mask 214 is for example obtained by lithography of a resin. The structure obtained at this stage of the method corresponds to the structure visible in FIG. 4.

Plasma etching is implemented by using a fluorocarbon plasma, for example C₂F₆, CHF₃ or CF₄, with a mixture of other gases such as Ar, N₂ or O₂, in order to etch the passivation layer 212 in accordance with the pattern of the etch mask 214.

The steps previously described in connection with FIG. 1 are then carried out to etch a part of the thickness of the AlGaN/GaN heterostructure formed by layers 206, 208 and 210. In the example described here, these steps are implemented to etch the entire thickness of layers 210 and 208, and a part of the thickness of layer 206. The total etched thickness is for example of between 20 nm and 400 nm.

The first etching 102 implemented by using a first plasma including chlorine may, for example, be used to etch the entire thickness of the layers 210 and 208, and to etch a large part of the desired thickness of the layer 206. Thus, the steps 104, 106 and 108 implemented one or more times only serve to etch a reduced remaining thickness of the layer material 206 until the desired depth is achieved, and thus allow the desired depth to be accurately achieved.

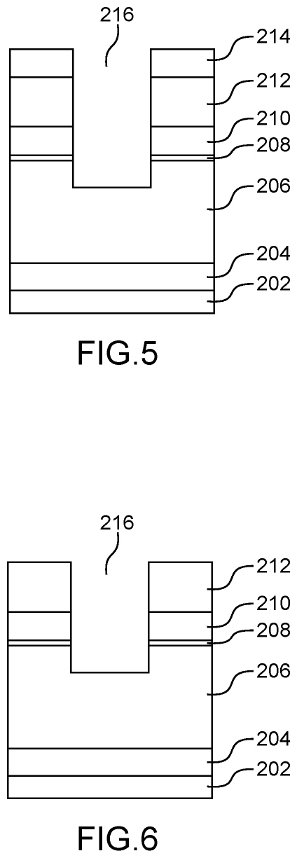

The implemented steps form a gate location 216 in the AlGaN/GaN heterostructure. A part of the thickness of the etch mask 214 is also consumed by these steps. The structure obtained at this stage of the method corresponds to the structure visible in FIG. 5.

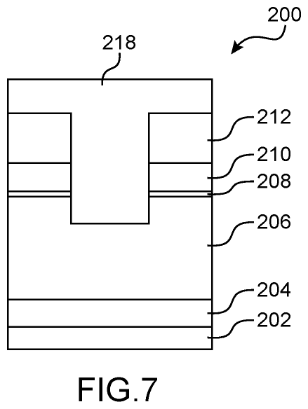

The etch mask 214 is then removed (the obtained structure visible in FIG. 6), and then the gate materials (gate dielectric and gate conductor) are deposited into the location 216 and onto the passivation layer 212, forming a gate 218. The structure resulting at the end of the method corresponds to the structure visible in FIG. 7, and schematically shows the component 200 made.

Similar steps may be implemented for making the contacts of the source and drain regions of the component 200.

Alternatively, the etching method described above may be implemented to make the contact locations of another type of power electronic component 200, for example a diode.

1. A method for etching at least one portion of a III-N material layer, including implementing the following steps of:
a) first etching of a first part of the thickness of the portion of the III-N material layer, implemented by using a first plasma including chlorine;
b) exposing at least one part of a remaining thickness of the portion of the III-N material layer to a second plasma including helium or hydrogen;
c) chlorinating the part of the remaining thickness of the portion of the III-N material layer, transforming the part of the remaining thickness of the portion of the III-N material layer into a chlorinated material layer;
d) second etching of the chlorinated material layer, implemented by using a third plasma including argon.

2. The etching method according to claim 1, wherein steps b), c) and d) are repeated one or more times until a desired etch depth is achieved.

3. The etching method according to claim 1, wherein step b) and/or step d) are implemented by subjecting the second plasma and/or the third plasma to a bias voltage of between 20V and 100V.

4. The etching method according to claim 1, wherein the part of the remaining thickness of the portion of the III-N material layer has a thickness of between 5 nm and 10 nm.

5. The etching method according to claim 1, wherein step c) is implemented by using a chlorine solution or a fourth plasma including Cl₂ and/or BCl₃.

6. The etching method according to claim 1, wherein steps b), c) and d) are implemented in a single ICP-RIE type etching equipment.

7. The etching method according to claim 1, wherein step b) and/or step d) are implemented with a pulsed plasma.

8. The etching method according to claim 1, wherein step b) and/or step d) are implemented:
by using a power source of between 100 W and 1000 W, and/or
in an etching chamber in which the pressure is between 0.67 Pa and 6.67 Pa, and/or
with a plasma flow between 10 sccm and 500 sccm, and/or
for a period of time of between 5 s and 20 s,
and/or wherein step c) is implemented:
by using a power source of between 100 W and 1000 W, and/or
in an etching chamber in which the pressure is between 1.33 Pa and 13.33 Pa, and/or
with a flow of between 10 sccm and 500 sccm, and/or
for a period of time of between 5 s and 30 s.

9. The etching method according to claim 1, wherein the III-N material layer includes GaN and/or AlGaN and/or AlN.

10. The etching method according to claim 1, wherein the III-N material layer is part of an AlGaN/GaN heterostructure.

11. A method for making at least one power electronic component, including implementing the following steps of:
making an AlGaN/GaN heterostructure;
making locations for electrical contacts of the power electronic component in the AlGaN/GaN heterostructure, including implementing an etching method according to claim 10.
